(19) United States
(12) Patent Application Publication
(10) Pub. No.: US 2025/0294678 A1
(43) Pub. Date: Sep. 18, 2025

(54) MULTILAYER RESIN SUBSTRATE AND ELECTRONIC DEVICE

(71) Applicant: Murata Manufacturing Co., Ltd., Nagaokakyo-shi (JP)

(72) Inventors: Shintaro HIRANO, Nagaokakyo-shi (JP); Tsuyoshi KATSUBE, Nagaokakyo-shi (JP); Keiichirou TAKAHASHI, Nagaokakyo-shi (JP); Daigo MATSUBARA, Nagaokakyo-shi (JP)

(73) Assignee: Murata Manufacturing Co., Ltd., Nagaokakyo-shi (JP)

(21) Appl. No.: 19/074,491

(22) Filed: Mar. 10, 2025

(30) Foreign Application Priority Data
Mar. 13, 2024 (JP) 2024-038638

(51) Int. Cl. H05K 1/03; B32B 7/022; B32B 7/12; B32B 15/09; B32B 15/20; B32B 27/36; B32B 27/38

(52) U.S. Cl. CPC H05K 1/036; B32B 7/022; B32B 7/12; B32B 15/09; B32B 15/20; B32B 27/36; B32B 27/38; B32B 2307/54; B32B 2457/00

(57) ABSTRACT

A multilayer resin substrate includes a multilayer substrate portion and a mounting portion, both a resin layer of the multilayer substrate portion and a resin layer of the mounting portion are layers made of, as a first component, a crystalline thermoplastic resin that is identical, the resin layer of the multilayer substrate portion and the resin layer of the mounting portion have a difference in endothermic peak temperature that appears first during temperature raising in a 1st-up chart when differential scanning calorimetry (DSC) is performed at a temperature raising rate of 10° C./min, the endothermic peak temperature of the resin layer of the multilayer substrate portion is lower as compared to the endothermic peak temperature of the resin layer of the mounting portion, and the resin layer of the multilayer substrate portion and the resin layer of the mounting portion are directly bonded to each other.

### CROSS-REFERENCE TO RELATED APPLICATION

This application claims priority to Japanese Patent Application No. JP 2024-038638 filed on Mar. 13, 2024. The entire contents of the above-identified application, including the specifications, drawings and claims, are incorporated herein by reference in their entirety.

### BACKGROUND

### 1. Field of the Disclosure

The present disclosure relates to a multilayer resin substrate including a multilayer substrate portion formed by laminating resin layers and a mounting portion mounted on the multilayer substrate portion or having a shape of being mounted on the multilayer substrate portion, and an electronic device including the multilayer resin substrate.

### 2. Description of the Related Art

International Publication No. 2017/051649 discloses a multilayer resin substrate including a plurality of resin layers, conductor layers each provided on one surface of each of the resin layers, and interlayer connection conductors formed in predetermined resin layers.

### SUMMARY

In a structure in which a region having a partially different thickness in a lamination direction is formed due to a difference in the number of laminated insulator layers to which the conductor layers are provided, a predetermined function implemented by an electronic component can be provided in a portion having a large thickness.

However, in bonding different materials to each other, it is difficult to ensure adhesion between the multilayer substrate and mounted components. In addition, since a rigid portion is constituted by the multilayer substrate and the mounted components mounted on the multilayer substrate, and the other portion of the multilayer substrate itself is a flexible portion, it is possible to have the flexible portion deformed. However, the rigid portion may also be deformed at the same time. Further, since stress is likely to concentrate on a boundary between the flexible portion and the rigid portion (root portion of the rigid portion), for example, a crack is likely to be generated at the boundary due to bending of the flexible portion.

Accordingly, it is an aspect of the present disclosure to provide a multilayer resin substrate that ensures adhesion between a multilayer substrate portion and a mounting portion mounted on the multilayer substrate portion or having a shape of being mounted on the multilayer substrate portion, and that suppresses deformation of a rigid portion constituted by the multilayer substrate portion and the mounting portion and generation of cracks at a boundary between a flexible portion and the rigid portion, and an electronic device including the multilayer resin substrate.

A multilayer resin substrate as an example of the present disclosure includes a multilayer substrate portion including a plurality of resin layers and conductor layers provided on predetermined resin layers of the plurality of resin layers, and a mounting portion including a resin layer and a conductor layer formed on the resin layer, the mounting portion being mounted on the multilayer substrate portion or having a shape of being mounted on the multilayer substrate portion in which both the resin layers of the multilayer substrate portion and the resin layer of the mounting portion are layers made of, as a first component, a crystalline thermoplastic resin that is identical, the resin layers of the multilayer substrate portion and the resin layer of the mounting portion have a difference in endothermic peak temperature that appears first during temperature raising in a 1st-up chart when differential scanning calorimetry is performed at a temperature raising rate of 10° C./min, the endothermic peak temperature of the resin layers of the multilayer substrate portion is lower as compared to the endothermic peak temperature of the resin layer of the mounting portion, and the resin layers of the multilayer substrate portion and the resin layer of the mounting portion are directly bonded to each other.

An electronic device as an example of the present disclosure includes the multilayer resin substrate and another substrate on which the multilayer resin substrate is mounted.

An electronic device as an example of the present disclosure includes the multilayer resin substrate and a housing for accommodating the multilayer resin substrate.

According to the present invention, a multilayer resin substrate that ensures adhesion between a multilayer substrate portion and a mounting portion with respect to the multilayer substrate portion, and that suppresses deformation of a rigid portion constituted by the multilayer substrate portion and the mounting portion and generation of cracks at a boundary between a flexible portion and the rigid portion, and an electronic device including the multilayer resin substrate are obtained.

### BRIEF DESCRIPTION OF THE DRAWINGS

FIG. 1 includes a lower part that is a sectional view of a multilayer resin substrate 301 according to a first embodiment, and an upper part that is a sectional view of a state before a mounting portion 201 is mounted with respect to a multilayer substrate portion 101;

FIG. 2 is a typical example of a diagram (chart) when differential scanning calorimetry (DSC) is performed, illustrating temperatures and displacement of the DSC in accordance with elapsed time;

FIG. 3 includes a lower part that is a sectional view of a multilayer resin substrate 302 according to a second embodiment, and an upper part that is a sectional view of the multilayer resin substrate 302 in the middle of manufacturing;

FIG. 4 includes a lower part that is a sectional view of a multilayer resin substrate 303 according to a third embodiment, and an upper part that is a plan view of a mounting portion 203;

FIG. 5 is a sectional view of a multilayer resin substrate 304 according to a fourth embodiment;

FIG. 6 is a sectional view of a multilayer resin substrate 305 according to a fifth embodiment;

FIG. 7 is a sectional view of a multilayer resin substrate 306 according to a sixth embodiment;

FIG. 8 is a sectional view of a multilayer resin substrate 307 according to a seventh embodiment;

FIG. 9 is a sectional view of a multilayer resin substrate 308 according to an eighth embodiment; and

FIG. 10 is a sectional view of an electronic device 409 according to a ninth embodiment.

### DESCRIPTION OF THE EMBODIMENTS

Hereinafter, a plurality of embodiments for carrying out the present disclosure will be described by giving some specific examples with reference to the accompanying drawings. In each of the drawings, the same portions are denoted by the same reference signs. In consideration of description of the main point or ease of understanding, the embodiment for carrying out the disclosure is divided into a plurality of embodiments and described, but partial omission, replacement, or combination of the configurations described in different embodiments is possible. In a second and subsequent embodiments, the description of the matters common to a first embodiment will be omitted, and only the different points will be described. In particular, similar actions and effects by similar configurations will not be described in each embodiment.

### First Embodiment

In a first embodiment, an example of a multilayer resin substrate will be described.

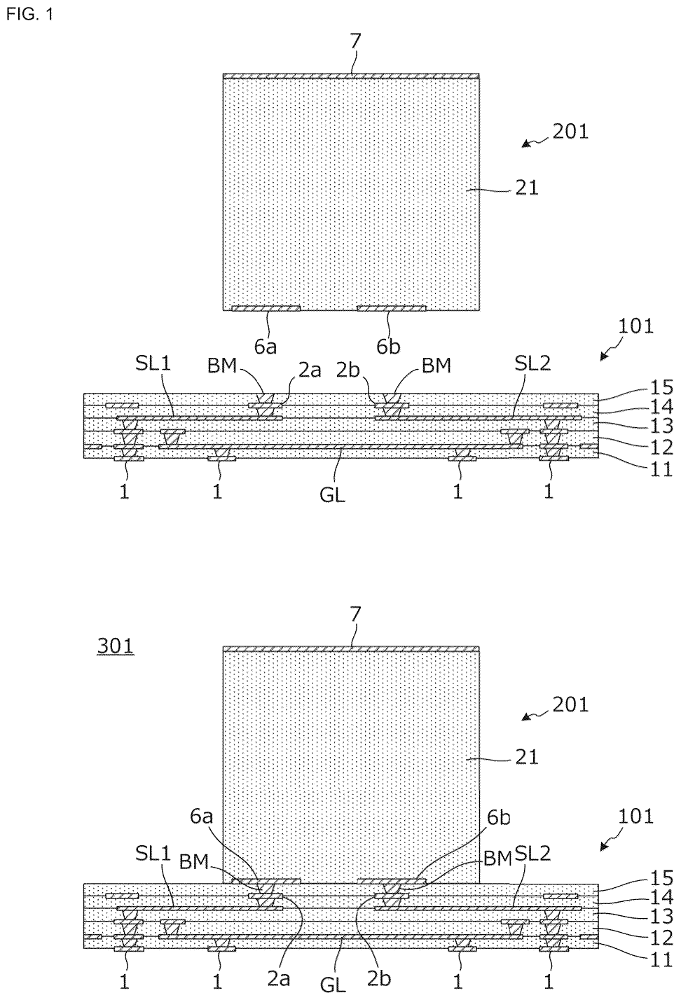

A lower part of FIG. 1 is a sectional view of a multilayer resin substrate 301 according to the first embodiment, and an upper part of FIG. 1 is a sectional view of a state before a mounting portion 201 is mounted with respect to a multilayer substrate portion 101. In a sectional view, lines that appear in the cross section (by cutting) are drawn, and lines that exist behind the cross section are omitted and not illustrated. The same applies to each embodiment that will be described later.

The multilayer resin substrate 301 includes the multilayer substrate portion 101 and the mounting portion 201.

The multilayer substrate portion 101 includes a plurality of resin layers 11, 12, 13, 14, and 15, and conductor layers and interlayer connection conductors provided on predetermined resin layers of the plurality of resin layers 11, 12, 13, 14, and 15. The conductor layers and the interlayer connection conductors are conductors containing Cu or Ag as a main component, for example.

The mounting portion 201 includes a resin layer and a resin layer 21 formed on the resin layer. Although the resin layer 21 is illustrated like a single layer in FIG. 1, the resin layer 21 is constituted of a single layer or a plurality of layers.

Connection conductors BM are formed by coating material in a cavity of a resin layer 15. The connection conductors BM are a heat melting metal such as solder. Pad electrodes 2a and 2b on a side of the multilayer substrate portion are formed on a lower layer of the connection conductors BM. In this example, the resin layers 11, 12, 13, 14, and 15 each have one surface to which a Cu foil is attached and constitute a multilayer body of thermoplastic resin sheets.

A conductor layer 7 is formed on or near an upper surface of the mounting portion 201 so that the mounting portion 201 acts as a circuit having predetermined electrical characteristics.

On a mounting surface (lower surface) of the mounting portion 201, terminal electrodes 6a and 6b are formed. The terminal electrodes 6a and 6b are electrically connected to the pad electrodes 2a and 2b formed on the multilayer substrate portion 101.

A plurality of outer electrodes 1 are formed on a lower surface of the multilayer substrate portion 101. The outer electrodes 1 are connected to pad electrodes formed on another substrate as will be described later so that the multilayer resin substrate 301 is mounted on the other substrate. Alternatively, as will be described later, an electronic component is mounted on the outer electrode 1, and thus a multilayer resin substrate on which the electronic component is mounted is constituted.

Inside the multilayer substrate portion 101, signal line conductive patterns SL1 and SL2 and a ground conductor layer GL are formed. The signal line conductive patterns SL1 and SL2, the ground conductor layer GL, and the resin layers between the signal line conductive patterns SL1 and SL2 and the ground conductor layer GL constitute two microstrip transmission lines.

The mounting portion 201 is subjected to a temperature raising/lowering process before being mounted on the multilayer substrate portion 101. As will be described later, this increases the crystallinity of the mounting portion 201, thus increasing the elastic modulus. That is, the elastic modulus of the multilayer substrate portion 101 is relatively reduced as compared to the mounting portion 201.

Here, the elastic modulus is measured by the following method. The elastic moduli of a crystalline thermoplastic resin as a first component in the resin layers 11, 12, 13, 14, and 15 of the multilayer substrate portion 101 and the resin layer 21 of the mounting portion 201 are measured by a nanoindentation method using a measuring instrument (TriboIndenter TI980, manufactured by Bruker Japan K.K.). The measurement mode at that time is (loading-holding-unloading): 5-2-5 seconds, load (indenter): 10 mN (Berkovich), number of measurement points: 5 points.

For example, when the crystalline thermoplastic resin is a liquid crystal polymer (LCP) resin, the elastic modulus of the multilayer substrate portion 101 is lower than the elastic modulus of the mounting portion 201 by 0.44 GPa.

As illustrated in FIG. 1, the mounting portion 201 is placed at a predetermined position of the multilayer substrate portion 101, and the whole structure is heated to a predetermined temperature and pressurized at a predetermined pressure. As a result, the connection conductors BM are melted, and the pad electrodes 2a and 2b on the side of the multilayer substrate portion are electrically connected to the terminal electrodes 6a and 6b on a side of the mounting portion 201.

Both the resin layers 11, 12, 13, 14, and 15 of the multilayer substrate portion 101 and the resin layer 21 of the mounting portion 201 are layers made of an identical crystalline thermoplastic resin as the first component. The resin layers 11, 12, 13, 14, and 15 of the multilayer substrate portion 101 and the resin layer 21 of the mounting portion 201 are directly bonded to each other by the above heating and pressing. This makes it possible to obtain high adhesion between the mounting portion 201 and the multilayer substrate portion 101.

Since both the resin layers 11, 12, 13, 14, and 15 of the multilayer substrate portion 101 and the resin layer 21 of the mounting portion 201 are made of the identical crystalline thermoplastic resin, higher adhesion force can be obtained between the mounting portion 201 and the multilayer substrate portion 101. Further, since the resin layers of the multilayer substrate portion 101 are the crystalline thermoplastic resin, the resin layers can be easily laminated all at once, and a separate adhesion process is not required, so that the number of overall processes can be reduced, and manufacturing can be done at a low cost.

Here, the term “first component” refers to a main component excluding accompanying layers, for example, even when there is an adhesive layer for bonding resin layers together. For example, both the resin layers 11, 12, 13, 14, and 15 of the multilayer substrate portion 101 and the resin layer 21 of the mounting portion 201 are layers made of the crystalline thermoplastic resin such as a wholly aromatic polyester resin or a thermoplastic polyimide resin.

The resin layers 11, 12, 13, 14, and 15 of the multilayer substrate portion 101 and the resin layer 21 of the mounting portion 201 have the following relationship. When differential scanning calorimetry (DSC) is performed at a temperature raising rate of 10° C./min for both the resin layers 11, 12, 13, 14, and 15 of the multilayer substrate portion 101 and the resin layer 21 of the mounting portion 201, there is a difference in endothermic peak temperature that appears first during temperature raising in a 1st-up chart, and the endothermic peak temperature of the resin layers 11, 12, 13, 14, and 15 of the multilayer substrate portion 101 is lower than the endothermic peak temperature of the resin layer 21 of the mounting portion 201.

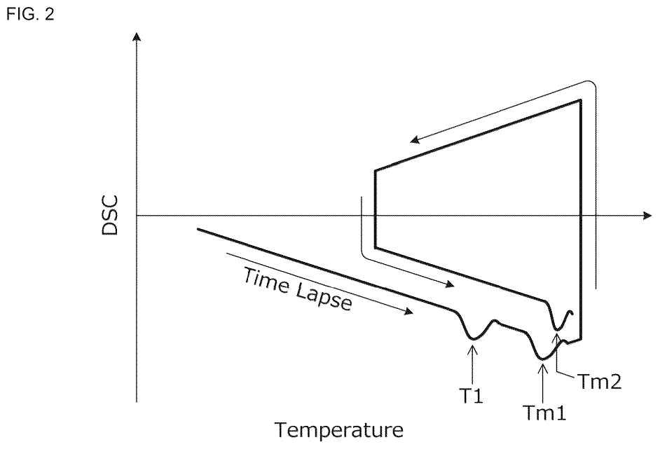

FIG. 2 is a typical example of a diagram (chart) when the differential scanning calorimetry (DSC) is performed, illustrating temperatures and displacement of the DSC in accordance with the elapsed time. First, using DSC8230 made by Rigaku Corporation, the temperature is raised from the room temperature at a rate of 10° C./min up to the temperature at which the crystalline thermoplastic resin completely melts, thereby completely melting the crystalline thermoplastic resin. At that time, among the endothermic peaks appearing during measurement, the endothermic peak temperature T1 that appears first is measured. However, broad and small peaks (area value: 0.8 mJ/mg or less) at the glass transition temperature are excluded. That is, temperatures of the broad and small peaks (shallow peak) at the glass transition temperature are not regarded as the endothermic peak temperature.

For example, when both the resin layers 11, 12, 13, 14, and 15 of the multilayer substrate portion 101 and the resin layer 21 of the mounting portion 201 are made of an identical liquid crystal polymer (LCP) resin as the first component, the endothermic peak temperature T1 of the resin layers 11, 12, 13, 14, and 15 of the multilayer substrate portion 101 is lower than the endothermic peak temperature T1 of the resin layer 21 of the mounting portion 201 by about 2.2° C.

In FIG. 2, Tm1 is a first melting point in the 1st-up chart. After the raised temperature exceeding the first melting point Tm1, the temperature is lowered from the endothermic peak temperature T1 and then raised again. The melting point (second melting point) in this temperature raising process is Tm2.

As mentioned above, “Both the resin layers 11, 12, 13, 14, and 15 of the multilayer substrate portion 101 and the resin layer 21 of the mounting portion 201 are layers made of the identical crystalline thermoplastic resin as the first component”. The above-mentioned “identical crystalline thermoplastic resin” is identified by a method to be described below.

First, the spectra of the crystalline thermoplastic resin as the first component for the mounting portion 201 and the multilayer substrate portion 101 are obtained by a Fourier transform infrared spectrophotometer (FT-IR). Then, it is confirmed that the mounting portion 201 and the multilayer substrate portion 101 have the identical peak of the spectrum and are made of the identical crystalline thermoplastic resin. Then, the mounting portion 201 and the multilayer substrate portion 101 are sampled by scraping off the crystalline thermoplastic resin as the first component, and second melting points Tm2 of the mount portion 201 and the multilayer substrate portion 101 are measured by performing the differential scanning calorimetry (DSC).

A measurement method of the second melting point Tm2 is as follows. As illustrated in FIG. 2, first, each crystalline thermoplastic resin is completely melted by raising the temperature from the room temperature to a temperature at which the crystalline thermoplastic resin is completely melted at a rate of 10° C./min. Thereafter, the temperature of the molten material of each crystalline thermoplastic resin is lowered to the room temperature at a rate of 10° C./min, and then raised at a rate of 10° C./min. The temperature of the endothermic peak that appears at the temperature at which the crystalline thermoplastic resin completely melts during this temperature raising is regarded as the second melting point Tm2 of the crystalline thermoplastic resin.

When the temperature difference between the second melting point Tm2 of the mounting portion 201 and the second melting point Tm2 of the multilayer substrate portion 101 is within 5° C., the crystalline thermoplastic resin of the mounting portion 201 and the crystalline thermoplastic resin of the multilayer substrate portion 101 are regarded as the identical crystalline thermoplastic resin.

According to the present embodiment, the following effects are exhibited.

(a) When the resin layers 11, 12, 13, 14, and 15 of the multilayer substrate portion 101 and the resin layer 21 of the mounting portion 201 are made of different materials, it is difficult to ensure adhesion between the multilayer substrate portion 101 and the mounting portion 201, but since the resin layers 11, 12, 13, 14, and 15 of the multilayer substrate portion 101 and the resin layer 21 of the mounting portion 201 are the layers made of the identical crystalline thermoplastic resin, adhesion therebetween is easily ensured.

(b) Since the elastic modulus of the multilayer substrate portion 101 is lower than the elastic modulus of the mounting portion 201, in a case in which the multilayer substrate portion 101 is bent while being heated to a temperature near the softening point of the multilayer substrate portion 101, the bendability of only the multilayer substrate portion 101 can be improved without deforming the mounting portion 201.

### Second Embodiment

In a second embodiment, a multilayer resin substrate in which a mounting structure of a mounting portion with respect to a multilayer substrate portion is different from that of the first embodiment will be exemplified.

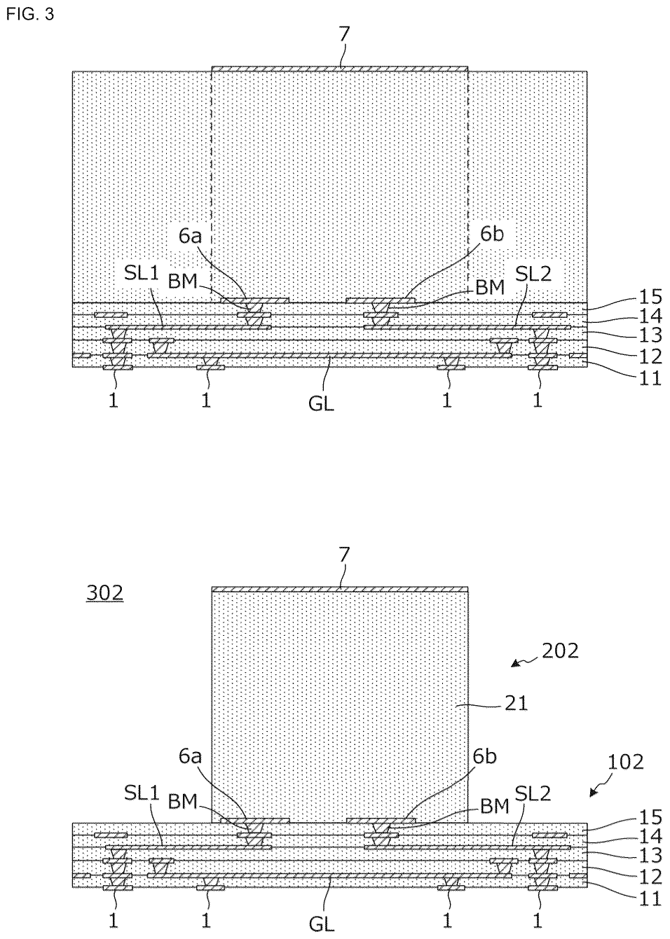

A lower part of FIG. 3 is a sectional view of a multilayer resin substrate 302 according to the second embodiment, and an upper part of FIG. 3 is a sectional view of the multilayer resin substrate 302 in the middle of manufacturing.

The multilayer resin substrate 302 includes a multilayer substrate portion 102 and a mounting portion 202.

As illustrated in the upper part of FIG. 3, the multilayer substrate portion 102 and the mounting portion 202 are initially in an integrated laminated substrate state. In a range illustrated in the upper part of FIG. 3, the left and right portions of the range illustrated with the broken line are cut away using a router by a predetermined amount so that the multilayer substrate portion 102 has a shape in which the mounting portion 202 is mounted.

Thereafter, by partial heat treatment, the mounting portion 202 is subjected to a temperature raising/lowering process without hardly raising the temperature of the multilayer substrate portion 101. The temperature at which the mounting portion 202 is heated is a temperature for providing characteristics that the endothermic peak temperature (T1) of a resin layer 21 of the mounting portion 202 is higher than the endothermic peak temperature (T1) of resin layers 11, 12, 13, 14, and 15 of the multilayer substrate portion 101.

According to the present embodiment, a process for mounting the mounting portion on the multilayer substrate portion is not required, and electrical connection and integrated bonding between the resins are facilitated.

### Third Embodiment

In a third embodiment, a multilayer resin substrate having a mounting portion with a structure different from that of the examples described in the first and second embodiments will be exemplified.

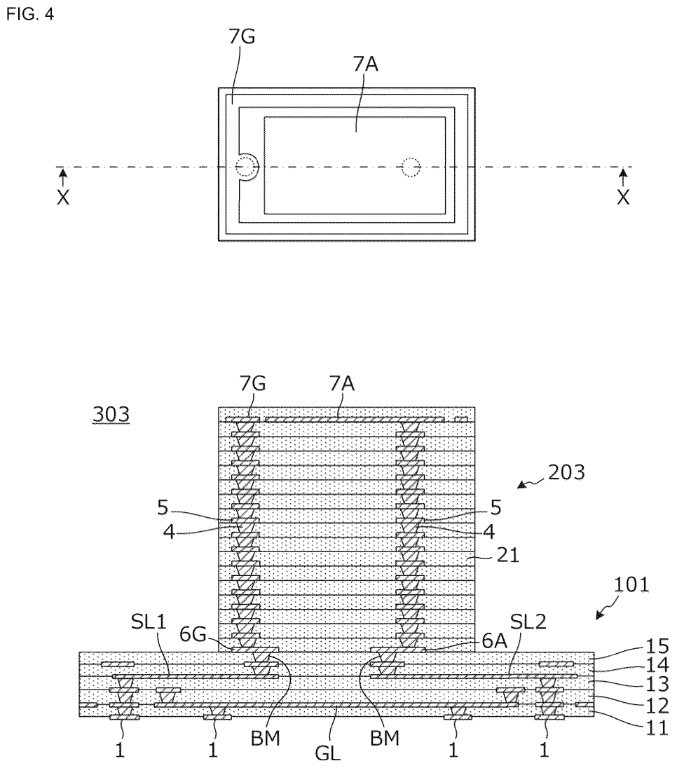

A lower part of FIG. 4 is a sectional view of a multilayer resin substrate 303 according to the third embodiment, and an upper part of FIG. 4 is a plan view of a mounting portion 203. In the upper part of FIG. 4, a dashed line indicates the cross-sectional position of the sectional view illustrated in the lower part of FIG. 4. However, a plan view of a multilayer substrate portion 101 is not illustrated.

The multilayer resin substrate 303 includes the multilayer substrate portion 101 and the mounting portion 203. The structure of the multilayer substrate portion 101 is the same as that of the multilayer substrate portion 101 illustrated in FIG. 1.

A radiation electrode 7A having a rectangular shape is formed on or near an upper surface of the mounting portion 203. A ground electrode 7G is formed around the radiation electrode 7A. That is, the mounting portion 203 is used as a patch antenna or a component that acts as a part of the patch antenna.

The mounting portion 203 is a multilayer body of resin layers 21 each having one surface to which a Cu foil is attached. On a mounting surface (lower surface) of the mounting portion 203, terminal electrodes 6A and 6G are formed. A multilayer body of a plurality of conductive foils 5 and a plurality of interlayer connection conductors 4 is formed between the terminal electrode 6A and the radiation electrode 7A. Similarly, a multilayer body including the plurality of conductive foils 5 and the plurality of interlayer connection conductors 4 is formed between the terminal electrode 6G and the ground electrode 7G. The interlayer connection conductor 4 electrically conducts the conductor layers made of the conductive foil 5 to each other. In this way, in the mounting portion 203, a laminating-direction conductor path is formed by laminating resin layers including the interlayer connection conductor 4 and the conductive foil 5 in contact with the interlayer connection conductor 4.

According to the present embodiment, unlike a structure in which interlayer connection is constituted by a penetrating through-hole, a structure without a cavity (hole) can be provided, and the strength of the mounting portion 203 can be improved.

Also in the third embodiment, the mounting portion 203 is subjected to the temperature raising/lowering process before the mounting portion 203 is mounted on the multilayer substrate portion 101. This increases the crystallinity of the mounting portion 203, thus increasing the elastic modulus. That is, the elastic modulus of the multilayer substrate portion 101 is relatively reduced as compared to the mounting portion 203.

### Fourth Embodiment

In a fourth embodiment, a multilayer resin substrate in which a structure of an interlayer connection conductor included in a mounting portion is different from that of the example described in the third embodiment will be exemplified.

FIG. 5 is a sectional view of a multilayer resin substrate 304 according to the fourth embodiment. The multilayer resin substrate 304 includes a multilayer substrate portion 101 and a mounting portion 204. The structure of the multilayer substrate portion 101 is the same as that of the multilayer substrate portion 101 illustrated in FIG. 1.

A radiation electrode 7A having a rectangular shape is formed on or near an upper surface of the mounting portion 204. A ground electrode 7G is formed around the radiation electrode 7A. The mounting portion 204 is used as a patch antenna or a component that acts as a part of the patch antenna, in a similar manner to the mounting portion 203 described in the third embodiment.

The mounting portion 204 is a multilayer body of resin layers 21 each having one surface to which a Cu foil is attached. On a mounting surface (lower surface) of the mounting portion 204, terminal electrodes 6A and 6G are formed. A multilayer body of a plurality of conductive foils 5 and a plurality of interlayer connection conductors 4 is formed between the terminal electrode 6A and the radiation electrode 7A. Similarly, a multilayer body including the plurality of conductive foils 5 and the plurality of interlayer connection conductors 4 is formed between the terminal electrode 6G and the ground electrode 7G. The interlayer connection conductors 4 are disposed at positions shifted in an X direction in each adjacent layer. In this way, the mounting portion 204 may be constituted with a laminating-direction conductor path in which the interlayer connection conductors 4 are disposed at positions not overlapping each other in a Z direction.

According to the present embodiment, unlike a structure in which interlayer connection is constituted by a penetrating through-hole, a structure without an opening (hole) can be provided, and the strength of the entire mounting portion 204 can be improved. Further, unlike a filled via formed by plating the inside of the through-hole, the via can be disposed at a different position in the inner layer of the mounting portion 204, and thus the degree of freedom in design is high.

### Fifth Embodiment

In a fifth embodiment, a multilayer resin substrate in which a structure of an interlayer connection conductor included in a mounting portion is different from that of the example described in the fourth embodiment will be exemplified.

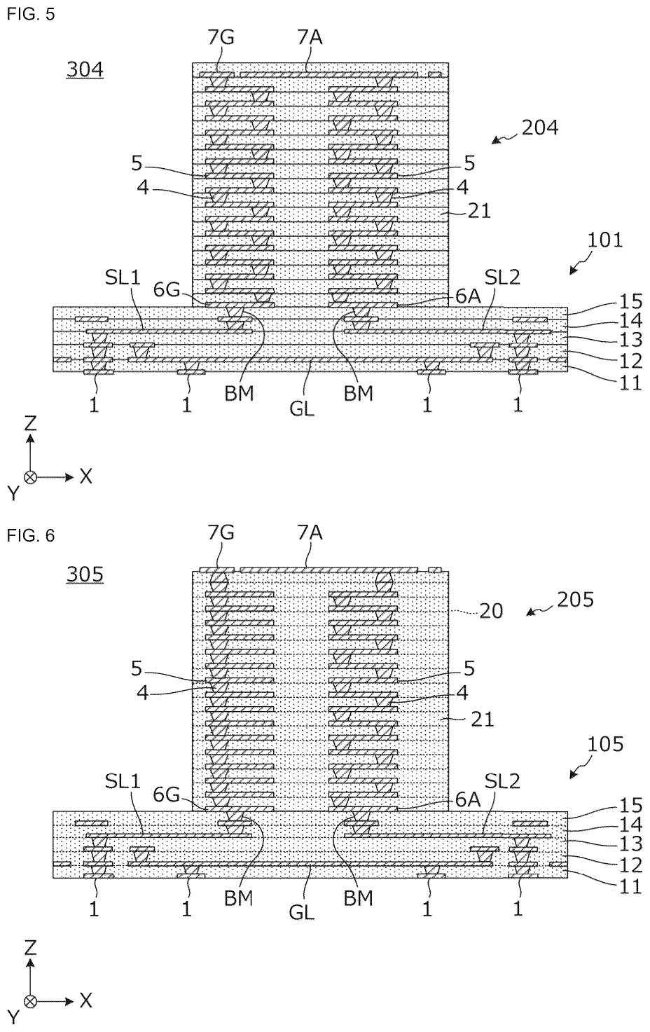

FIG. 6 is a sectional view of a multilayer resin substrate 305 according to the fifth embodiment. The multilayer resin substrate 305 includes a multilayer substrate portion 105 and a mounting portion 205. The structure of the multilayer substrate portion 105 is the same as that of the multilayer substrate portion 105 illustrated in FIG. 1. However, resin layers 11, 12, 13, 14, and 15 are adhered to each other with adhesive layers indicated by broken lines.

A radiation electrode 7A having a rectangular shape is formed on or near an upper surface of the mounting portion 205. A ground electrode 7G is formed around the radiation electrode 7A. The mounting portion 205 is used as a patch antenna or a component that acts as a part of the patch antenna, in a similar manner to the mounting portion 203 described in the third embodiment.

The mounting portion 205 is a multilayer body in which resin layers 21 each having one surface to which a Cu foil is attached are adhered by adhesive layers 20 indicated by a broken line. On a mounting surface (lower surface) of the mounting portion 205, terminal electrodes 6A and 6G are formed. A multilayer body of a plurality of conductive foils 5 and a plurality of interlayer connection conductors 4 is formed between the terminal electrode 6A and the radiation electrode 7A. Similarly, a multilayer body including the plurality of conductive foils 5 and the plurality of interlayer connection conductors 4 is formed between the terminal electrode 6G and the ground electrode 7G. Interlayer connection conductors 4 aligned in a Z direction are disposed between the terminal electrode 6G and the ground electrodes 7G, and the interlayer connection conductors 4 alternately shifted in an X direction are disposed between the terminal electrode 6A and the radiation electrode 7A.

The radiation electrode 7A and the ground electrode 7G made of Cu foils are formed on an upper surface of the uppermost resin layer of the plurality of resin layers 21. In this way, the radiation electrode 7A and the ground electrode 7G may be exposed on the outer surface of the mounting portion 205.

### Sixth Embodiment

In a sixth embodiment, a multilayer resin substrate including an electronic component will be exemplified.

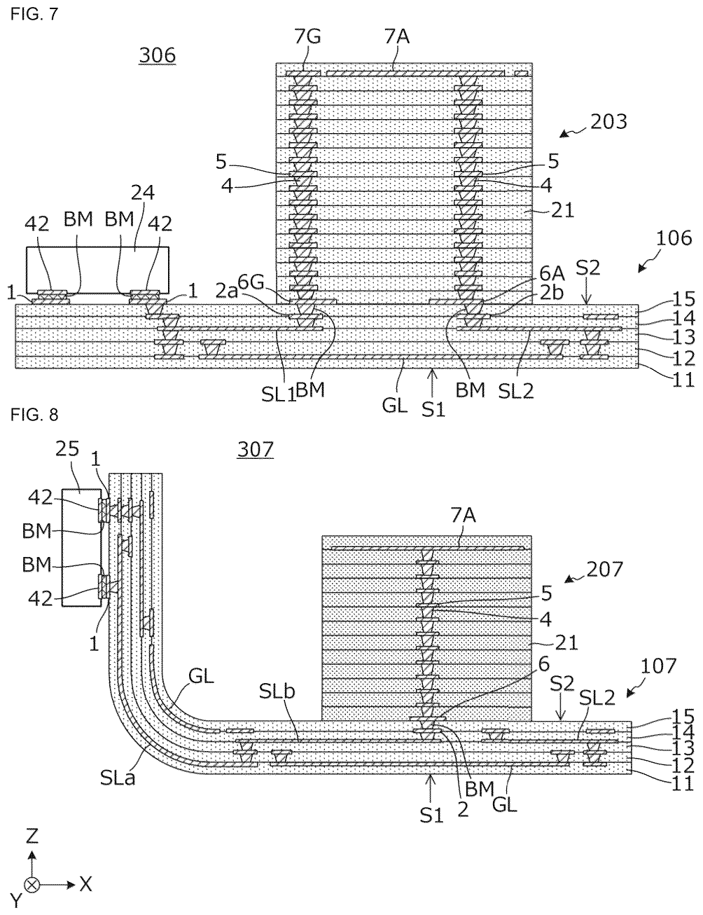

FIG. 7 is a sectional view of a multilayer resin substrate 306 according to the sixth embodiment. The multilayer resin substrate 306 includes a multilayer substrate portion 106, a mounting portion 203, and an electronic component 24. The illustration of hatching is omitted for the electronic component 24.

The multilayer substrate portion 106 includes a plurality of resin layers 11, 12, 13, 14, and 15, and conductor layers and interlayer connection conductors provided on predetermined resin layers among the plurality of resin layers.

The mounting portion 203 is the same as the mounting portion 203 described in the third embodiment.

A pad electrode 42 on a side of the component is connected to an outer electrode 1 of the multilayer substrate portion 106 with a connection conductor BM interposed therebetween. The connection conductor BM is a heat melting metal such as solder.

The electronic component 24 is, for example, an IC that amplifies power of a transmission signal and feeds the amplified power to an antenna, or an IC that amplifies a reception signal received by the antenna.

According to the present embodiment, the electronic component 24 has excellent mounting characteristics with respect to the multilayer substrate portion 106, and therefore the electronic component 24 can be easily mounted on the multilayer substrate portion 106.

### Seventh Embodiment

In a seventh embodiment, a multilayer resin substrate including a curved multilayer substrate portion will be exemplified.

FIG. 8 is a sectional view of a multilayer resin substrate 307 according to the seventh embodiment. The multilayer resin substrate 307 includes a multilayer substrate portion 107 and a connector 25 mounted thereon. The illustration of hatching is omitted for the connector 25.

The mounting portion 207 includes a radiation electrode 7A formed on or near an upper surface of the mounting portion 207 so that the mounting portion 207 acts as a patch antenna or a part of the patch antenna.

A terminal electrode 6 is formed on a mounting surface (lower surface) of the mounting portion 207. A multilayer body of a plurality of conductive foils 5 and a plurality of interlayer connection conductors 4 is formed between the terminal electrode 6 and the radiation electrode 7A. In this way, in the mounting portion 207, a laminating-direction conductor path is formed by laminating resin layers including the interlayer connection conductor 4 and the conductive foil 5 in contact with the interlayer connection conductor 4.

Signal line conductive patterns SLa and SLb and a ground conductor layer GL are formed inside the multilayer substrate portion 107. The signal line conductive patterns SLa and SLb, the ground conductor layer GL, and the resin layers between the signal line conductive patterns SLa and SLb and the ground conductor layer GL form a microstrip transmission line.

The plurality of outer electrodes 1 are exposed on a first surface S1 of the multilayer substrate portion 107. A pad electrode 2 is formed on a second surface S2 of the multilayer substrate portion 107. The terminal electrode 6 of the mounting portion 207 is bonded to the pad electrode 2 with a connection conductor BM interposed therebetween. A lower surface of the lowermost resin layer 21 of the mounting portion 207 is bonded to a resin layer 15 of the multilayer substrate portion 107.

A pad electrode 42 on a side of the component is connected to an outer electrode 1 of the multilayer substrate portion 107 with the connection conductor BM interposed therebetween. The connection conductor BM is a heat melting metal such as solder.

In the example illustrated in FIG. 8, the multilayer substrate portion 107 is curved (bent) by 90° in a direction of the mounting surface of the mounting portion 207 along an X-Z plane. That is, the multilayer substrate portion 107 includes a bent portion.

The connector 25 is connected to the patch antenna constituted by mounting the mounting portion 207.

According to the present embodiment, since the multilayer substrate portion 107 provided with the bent portion by heating can be disposed in an arbitrary space, the multilayer resin substrate 307 having a predetermined shape as a whole can be constituted.

### Eighth Embodiment

In an eighth embodiment, an example is described in which a structure of a boundary portion between a multilayer substrate portion and a mounting portion is different from that of the multilayer resin substrate described so far.

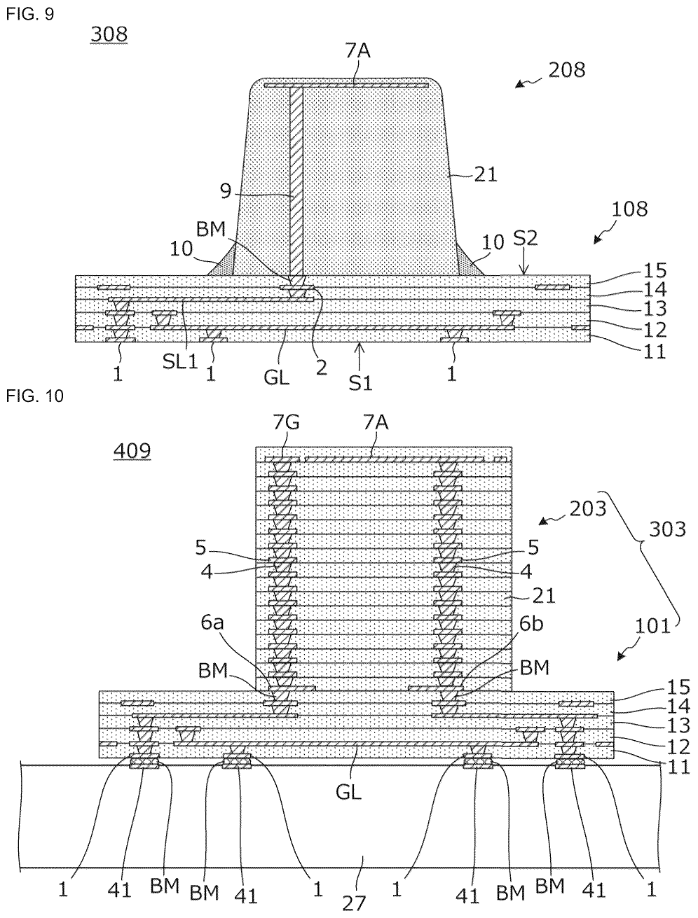

FIG. 9 is a sectional view of a multilayer resin substrate 308 according to the eighth embodiment. The multilayer resin substrate 308 includes a multilayer substrate portion 108 and a mounting portion 208. The multilayer substrate portion 108 includes a plurality of resin layers 11, 12, 13, 14, and 15, and conductor layers and interlayer connection conductors provided on predetermined resin layers among the plurality of resin layers. A connection conductor BM is formed by coating in a cavity of the resin layer 15. The connection conductor BM is a heat melting metal such as solder. A pad electrode 2 on a side of the multilayer substrate portion is formed on a lower layer of the connection conductor BM.

The mounting portion 208 includes a radiation electrode 7A formed on or near an upper surface of the mounting portion 208 so that the mounting portion 208 acts as a patch antenna or a part of the patch antenna.

A filled plating through-hole 9 is formed inside a resin layer 21 and is conducted to the radiation electrode 7A.

A boundary between the mounting portion 208 and the multilayer substrate portion 108 (the base portion of the mounting portion 208) is covered with a resin material 10. The resin material 10 has a structure that covers a second surface S2 of the multilayer substrate portion 108, so that a root portion of the mounting portion 208 is pressed against the multilayer substrate portion 108.

The resin material 10 is, for example, an epoxy resin, and is coated and formed in a state in which the mounting portion 208 is mounted on the multilayer substrate portion 108. The resin material 10 is preferably a material having a higher Young's modulus than that of the material constituting the resin layer of the multilayer substrate portion 108. The Young's modulus is obtained by conducting a nanoindenter test according to the standards of JIS Z 2255 and ISO 14577. For example, the Young's modulus can be obtained from load-displacement data using a Micro nanoindentation instrument manufactured by KLA Corporation.

Since the mounting portion of the mounting portion 208 is rigid and the other portions are flexible, when an external force to bend the multilayer resin substrate 308 is applied thereto, stress is likely to concentrate on the root portion of the mounting portion 208.

In the multilayer resin substrate 308 according to the present embodiment, since the bonding force between the multilayer substrate portion 108 and the mounting portion 208 is high, cracking and chipping at the interface between the multilayer substrate portion 108 and the mounting portion 208 will be prevented. In addition, since the mounting portion 208 has high rigidity with respect to the multilayer substrate portion 108, deformation such as inclination of the mounting portion 208 is suppressed. As a result, the deviation of the radiation direction (directivity) of the antenna is suppressed.

Although FIG. 9 illustrates an example in which the resin material 10 is a member separate from the multilayer substrate portion 108 and the mounting portion 208, a shape of the resin material 10 may be formed from the multilayer substrate portion 108 or the mounting portion 208. That is, after the mounting portion 208 is placed on the multilayer substrate portion 108, a pressure is applied to press the mounting portion 208 into the multilayer substrate portion 108, and the multilayer substrate portion 108 is heated. As a result, the mounting portion 208 is sunk into the multilayer substrate portion 108, and the resin layer of the upper layer of the multilayer substrate portion 108 is raised to the root portion of the mounting portion 208, and the raised portion is formed as the resin material 10. Alternatively, the resin material 10 is formed by melting the root portion of the mounting portion 208 by the pressure and heat.

### Ninth Embodiment

In a ninth embodiment, an electronic device including a multilayer resin substrate and another substrate will be exemplified.

FIG. 10 is a sectional view of an electronic device 409 according to the ninth embodiment. The electronic device 409 includes another substrate 27, and a multilayer substrate portion 101 and a mounting portion 203 mounted thereon. The illustration of hatching is omitted for the other substrate 27.

The constitution of the multilayer resin substrate 303 made of the multilayer substrate portion 101 and the mounting portion 203 is the same as that of the multilayer resin substrate 303 illustrated in FIG. 4 in the third embodiment.

An outer electrode 1 is formed on the mounting surface (lower surface) of the multilayer resin substrate 303. On a mounting surface (upper surface) of the other substrate 27, a pad electrode 41 on a side of the other substrate is formed.

The outer electrode 1 of the multilayer substrate portion 101 is connected to the pad electrode 41 on a side of the other substrate with a connection conductor BM interposed therebetween. The connection conductor BM is a heat melting metal such as solder.

The other substrate 27 is, for example, a rigid glass epoxy resin substrate.

### Tenth Embodiment

In a tenth embodiment, an electronic device including a housing will be exemplified.

An electronic device according to the present embodiment includes any one of the multilayer resin substrates described in the first to ninth embodiments, and a housing for accommodating the multilayer resin substrate.

The housing for accommodating the multilayer resin substrate has a size and a shape capable of accommodating (incorporating) the multilayer resin substrate.

While various embodiments according to the present invention have been presented, these are merely examples and are not intended to limit the scope of the present invention. Various omissions, substitutions, and changes can be made to the embodiments according to the present invention without departing from the gist of the invention. The embodiments in which various omissions, substitutions, and changes are made are included in the scope of the present invention and the gist of the invention, and are included in the invention described in the claims of the present application and the scope of equivalents thereof.

For example, in each of the embodiments, an example in which a protective film is formed on the multilayer substrate portion, the mounting portion, or the like is not described, but the protective film may be formed on a predetermined portion or the entire surface of the outer surface.

In each of the embodiments, the microstrip line is constituted by forming the signal line conductive pattern SL and the ground conductor layer GL. However, the constitution of the multilayer resin substrate is not limited to the constitution in which the transmission line is connected to the mounting portion.

The multilayer resin substrate and the electronic device of the present invention may be provided in the following aspects.

<1>

A multilayer resin substrate, comprising:
a multilayer substrate portion including a plurality of resin layers and conductor layers provided on predetermined resin layers of the plurality of resin layers; and
a mounting portion including a resin layer and a conductor layer formed on the resin layer, the mounting portion being mounted on the multilayer substrate portion or having a shape of being mounted on the multilayer substrate portion, wherein
both the resin layers of the multilayer substrate portion and the resin layer of the mounting portion are layers made of, as a first component, a crystalline thermoplastic resin that is identical,
the resin layers of the multilayer substrate portion and the resin layer of the mounting portion have a difference in endothermic peak temperature that appears first during temperature raising in a 1st-up chart when differential scanning calorimetry is performed at a temperature raising rate of 10° C./min,
the endothermic peak temperature of the resin layers of the multilayer substrate portion is lower as compared to the endothermic peak temperature of the resin layer of the mounting portion, and
the resin layers of the multilayer substrate portion and the resin layer of the mounting portion are directly bonded to each other.
   <2>

The multilayer resin substrate according to <1>, wherein
the crystalline thermoplastic resin is a wholly aromatic polyester resin.
   <3>

The multilayer resin substrate according to <1> or <2>, wherein
the mounting portion has higher crystallinity as compared to the multilayer substrate portion due to a temperature raising/lowering process performed on the mounting portion.
   <4>

The multilayer resin substrate according to any one of <1> to <3>, wherein
an elastic modulus of the multilayer substrate portion is lower than an elastic modulus of the mounting portion.
   <5>

The multilayer resin substrate according to any one of <1> to <4>, wherein
the mounting portion includes a plurality of resin layers, conductor layers formed on the resin layers, and interlayer connection conductors for electrically conducting the conductor layers to each other.
   <6>

The multilayer resin substrate according to <5>, wherein
the conductor layers formed on the mounting portion includes a radiation electrode and the interlayer connection conductors conducting to the radiation electrode.
   <7>

The multilayer resin substrate according to any one of <1> to <6>, wherein
the multilayer substrate portion includes an interlayer connection conductor on an upper surface of the multilayer substrate portion,
the mounting portion includes a terminal electrode on a lower surface of the mounting portion, and
the terminal electrode of the mounting portion is electrically connected to the interlayer connection conductor of the multilayer substrate portion.
   <8>

The multilayer resin substrate according to any one of <1> to <7>, wherein
a transmission line is formed in the multilayer substrate portion.
   <9>

The multilayer resin substrate according to any one of <1> to <8>, wherein
the multilayer substrate portion includes a bent portion.
   <10>

The multilayer resin substrate according to any one of <1> to <9>, wherein
the multilayer substrate portion is provided with an outer electrode, and includes a component connected to the outer electrode and mounted on the multilayer substrate portion.
   <11>

The multilayer resin substrate according to any one of <1> to <10>, further comprising:
a resin material covering a boundary between the mounting portion and the multilayer substrate portion.
   <12>

An electronic device, comprising:
the multilayer resin substrate according to any one of <1> to <11>; and
another substrate on which the multilayer resin substrate is mounted.
   <13>

An electronic device, comprising:
the multilayer resin substrate according to any one of <1> to <11>; and
a housing for accommodating the multilayer resin substrate.

What is claimed is:

1. A multilayer resin substrate, comprising:
a multilayer substrate portion including a plurality of resin layers and conductor layers provided on predetermined resin layers of the plurality of resin layers; and
a mounting portion including a resin layer and a conductor layer formed on the resin layer, the mounting portion being mounted on the multilayer substrate portion or having a shape matched to the multilayer substrate portion to support being mounted on the multilayer substrate portion, wherein
both the resin layers of the multilayer substrate portion and the resin layer of the mounting portion are made of an identical material of, as a first component, a crystalline thermoplastic resin,
respective endothermic peak temperatures of the resin layers of the multilayer substrate portion and of the resin layer of the mounting portion that appear first during temperature raising in a 1st-up chart during differential scanning calorimetry at a temperature raising rate of 10° C./min are different,
the endothermic peak temperature of the resin layers of the multilayer substrate portion is lower than the endothermic peak temperature of the resin layer of the mounting portion, and
the resin layers of the multilayer substrate portion and the resin layer of the mounting portion are directly bonded to each other.

2. The multilayer resin substrate according to claim 1, wherein
the crystalline thermoplastic resin is a wholly aromatic polyester resin.

3. The multilayer resin substrate according to claim 1, wherein
the mounting portion has higher crystallinity as compared to the multilayer substrate portion.

4. The multilayer resin substrate according to claim 2, wherein
the mounting portion has higher crystallinity as compared to the multilayer substrate portion.

5. The multilayer resin substrate according to claim 1, wherein
an elastic modulus of the multilayer substrate portion is lower than an elastic modulus of the mounting portion.

6. The multilayer resin substrate according to claim 2, wherein
an elastic modulus of the multilayer substrate portion is lower than an elastic modulus of the mounting portion.

7. The multilayer resin substrate according to claim 1, wherein
the mounting portion includes another plurality of resin layers, conductor layers formed on the another plurality of resin layers, and interlayer connection conductors that electrically connect the conductor layers to each other.

8. The multilayer resin substrate according to claim 2, wherein
the mounting portion includes another plurality of resin layers, conductor layers formed on the another plurality of resin layers, and interlayer connection conductors that electrically connect the conductor layers to each other.

9. The multilayer resin substrate according to claim 7, wherein
the conductor layers formed on the mounting portion includes a radiation electrode and at least one of the interlayer connection conductors electrically connect to the radiation electrode.

10. The multilayer resin substrate according to claim 8, wherein
the conductor layers formed on the mounting portion includes a radiation electrode and at least one of the interlayer connection conductors electrically connect to the radiation electrode.

11. The multilayer resin substrate according to claim 1, wherein
the multilayer substrate portion includes an interlayer connection conductor on an upper surface of the multilayer substrate portion,
the mounting portion includes a terminal electrode on a lower surface of the mounting portion, and
the terminal electrode of the mounting portion is electrically connected to the interlayer connection conductor of the multilayer substrate portion.

12. The multilayer resin substrate according to claim 2, wherein
the multilayer substrate portion includes an interlayer connection conductor on an upper surface of the multilayer substrate portion,
the mounting portion includes a terminal electrode on a lower surface of the mounting portion, and
the terminal electrode of the mounting portion is electrically connected to the interlayer connection conductor of the multilayer substrate portion.

13. The multilayer resin substrate according to claim 1, further comprising:
a transmission line formed in the multilayer substrate portion.

14. The multilayer resin substrate according to claim 2, further comprising:
a transmission line formed in the multilayer substrate portion.

15. The multilayer resin substrate according to claim 1, wherein
the multilayer substrate portion includes a bent portion.

16. The multilayer resin substrate according to claim 1, wherein
the multilayer substrate portion includes an outer electrode, and a component connected to the outer electrode and mounted on the multilayer substrate portion.

17. The multilayer resin substrate according to claim 1, further comprising:
a resin material that covers a boundary between the mounting portion and the multilayer substrate portion.

18. An electronic device, comprising:
the multilayer resin substrate according to claim 1; and
another substrate on which the multilayer resin substrate is mounted.

19. An electronic device, comprising:
the multilayer resin substrate according to claim 2; and
another substrate on which the multilayer resin substrate is mounted.

20. An electronic device, comprising:
the multilayer resin substrate according to claim 1; and
a housing that accommodates the multilayer resin substrate.
